(19) United States
(12) Patent Application Publication
(10) Pub. No.: US 2005/0258472 A1
(43) Pub. Date: Nov. 24, 2005

(54) Nonvolatile semiconductor memory device for increasing coupling ratio, and of fabrication method thereof

(75) Inventors: Sung-Taeg Kang, Seoul (KR); Seong-Gyun Kim, Seongnam-si (KR); Ji-Hoon Park, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/108,946

(22) Filed: Apr. 18, 2005

(30) Foreign Application Priority Data
May 21, 2004 (KR) 2004-36370

(51) Int. Cl. H01L 29/788

(52) U.S. Cl. 257/315

(57) ABSTRACT

A nonvolatile semiconductor memory device includes: a gate stack which has a tunnel oxide film, a floating gate, an interlayer insulating film and a control gate sequentially formed on a semiconductor substrate; a first diffusion region which is formed in the semiconductor substrate on one side surface of the gate stack; a second diffusion region which is formed in the semiconductor substrate on the other side surface of the gate stack; and a channel region which is formed in the semiconductor substrate between the first and second diffusion regions, wherein the floating gate has both side surfaces wave-shaped in the direction of a channel length.

### CROSS-REFERENCE TO RELATED APPLICATION

This application claims the priority under 35 U.S.C. §119 to Korean Patent Application No. 2004-36370, filed on May 21, 2004, in the Korean Intellectual Property Office, the disclosure of which is incorporated by reference herein.

### BACKGROUND OF THE INVENTION

1. Field of the Invention

The present invention relates to a nonvolatile semiconductor memory device, and more particularly, to a nonvolatile semiconductor memory device for increasing the coupling ratio.

2. Description of the Related Art

Generally, there are several kinds of semiconductor memory device. Among the semiconductor memory devices, Random Access Memory (RAM) is volatile, i.e., stored information is lost when power is removed, whereas Read Only Memory (ROM) is nonvolatile, i.e., it retains stored information even when power is removed. An Electrically Erasable and Programmable Read Only Memory (EEPROM) device is another nonvolatile semiconductor memory device.

FIG. 1 is a cell layout illustrating a conventional EEPROM device, and FIG. 2 is a sectional view taken along line II-II′ of FIG. 1.

In detail, a memory gate oxide film 12 and a tunnel oxide film 14 are formed on a semiconductor substrate 10. The tunnel oxide film 14 that is formed at a portion of the semiconductor substrate 10 is thinner than the memory gate oxide film 12. A floating gate 16 is formed on the memory gate oxide film 12 and the tunnel oxide film 14. In FIG. 1, a reference numeral 40 denotes a mask pattern for defining the floating gate 16. The defined portion denoted by the reference numeral 40 represents an etched portion. An interlayer insulating film 18 and a control gate 20 are formed on the floating gate 16.

A source region 22 is formed in the semiconductor substrate 10 in alignment with one sidewall of the floating gate 16 and the control gate 20, and the floating junction region 24 is formed in the semiconductor substrate 10 below and to the right of the tunnel oxide film 14. The source region 22 and the floating junction region 24 are formed using N⁺ impurities when the semiconductor substrate 10 is a P-type silicon substrate. The tunnel oxide film 14, the floating gate 16, the interlayer insulating film 18 and the control gate 20 are sequentially formed to constitute a gate stack. The gate stack, the source region 22 and the floating junction region 24 constitute a memory transistor (MTR).

A selection gate oxide film 26 is spaced apart from the memory transistor (MTR) on the semiconductor substrate 10. A first conductive film pattern 28, an insulating film pattern 30 and a second conductive film pattern 32 are formed on the selection gate oxide film 26 to constitute a gate 34. A drain region 36 is formed in the semiconductor substrate 10 at the right side of the gate 34. A bit line (not shown) is connected to the drain region 36. The drain region 36 is formed using the N⁺ impurities when the semiconductor substrate 10 is the P-type silicon substrate. The selection gate oxide film 26, the gate 34, the floating junction region 24 and the drain region 36 constitute a selection transistor (STR).

In the conventional nonvolatile memory device, a voltage difference between the control gate 20 and the floating junction region 24 causes current to flow through the tunnel oxide film 14. Accordingly, electrons are injected into or emitted from the floating gate 16 to erase or program the cell.

However, the operation voltage is determined based on the coupling ratio, that is, how much the voltage of the control gate is induced to the floating gate. The operation voltage is used when the nonvolatile memory device performs the programming and erasing operations. Accordingly, the coupling ratio should be increased to decrease the operation voltage. However, when the nonvolatile memory device is small, the capacitance between the floating gate and the control gate is decreased, thereby decreasing the coupling ratio.

A conventional method for increasing the coupling ratio is to decrease the thickness of the interlayer insulating film or the tunnel oxide film to increase the capacitance between the floating gate and the control gate. However, this drastically reduces charge retention, and there is a limit in patterning and reliability.

Further, a method of embossing the surface of the floating gate or increasing the height of the floating gate has been proposed to increase the coupling ratio. However, embossing the surface of the floating gate also reduces charge retention, and increasing the height of the floating gate results in a tall gate stack, which is difficult to etch.

### SUMMARY OF THE INVENTION

According to an aspect of the present invention, there is provided a nonvolatile semiconductor memory device including: a gate stack which comprises a tunnel oxide film, a floating gate, an interlayer insulating film and a control gate sequentially formed on a semiconductor substrate; a first diffusion region which is formed in the semiconductor substrate on one side surface of the gate stack; a second diffusion region which is formed in the semiconductor substrate on the other side surface of the gate stack; and a channel region which is formed in the semiconductor substrate between the first and second diffusion regions, wherein the floating gate has both side surfaces wave-shaped in the direction of a channel length.

According to another aspect of the present invention, there is provided a nonvolatile semiconductor memory device including: a memory transistor and a selection transistor which are formed on a semiconductor substrate, wherein the memory transistor comprises: a memory gate oxide film which is formed on the semiconductor substrate; a floating gate which is formed on the memory gate oxide film having both side surfaces wave-shaped in the direction of a channel length; an interlayer insulating film and a control gate which are sequentially formed on the floating gate; a source region which is formed in the semiconductor substrate in alignment with one sidewall of the floating gate and the control gate; and a floating junction region which is formed in the semiconductor substrate in alignment with the other sidewall of the floating gate and the control gate, and the selection transistor comprises: a selection gate oxide film which is spaced apart from the memory transistor; a selection gate which is formed on the selection gate oxide film; a source region which uses the floating junction region of the memory transistor; and a drain region which is formed in alignment with the other sidewall of the selection gate.

According to a further aspect of the present invention, there is provided a nonvolatile semiconductor memory device comprising: a tunnel oxide film which is formed on a semiconductor substrate; a floating gate which is formed on the tunnel oxide film having both side surfaces wave-shaped in the direction of a channel length; an interlayer insulating film and a control gate which are sequentially formed on the floating gate; a source region which is formed in the semiconductor substrate in alignment with one sidewall of the floating gate and the control gate; and a drain region which is formed in the semiconductor substrate in alignment with the other sidewall of the floating gate and the control gate.

### BRIEF DESCRIPTION OF THE DRAWINGS

The above and other features of the present invention will become more apparent by describing in detail exemplary embodiments thereof with reference to the attached drawings in which:

FIG. 1 is a cell layout illustrating a conventional Electrically Erasable and Programmable Read Only Memory (EEPROM) device;

FIG. 2 is a sectional view taken along line II-II′ of FIG. 1;

FIG. 3 is a cell layout illustrating an EEPROM device according to the present invention;

FIG. 4 is a sectional view taken along line IV-IV′ of FIG. 3;

FIG. 5 is a cell layout illustrating a flash memory device according to the present invention;

FIG. 6 is a sectional view taken along line VI-VI′ of FIG. 5;

FIG. 7 is a view illustrating a conventional process of patterning a floating gate of a nonvolatile semiconductor memory device;

FIGS. 8 and 9 are views illustrating a process of patterning a floating gate of a nonvolatile semiconductor memory device according to the present invention;

FIG. 10 is a simulated perspective view of a floating gate of a nonvolatile semiconductor memory device according to the present invention; and

FIG. 11 is a flowchart illustrating a method of fabricating a nonvolatile semiconductor memory device according to the present invention.

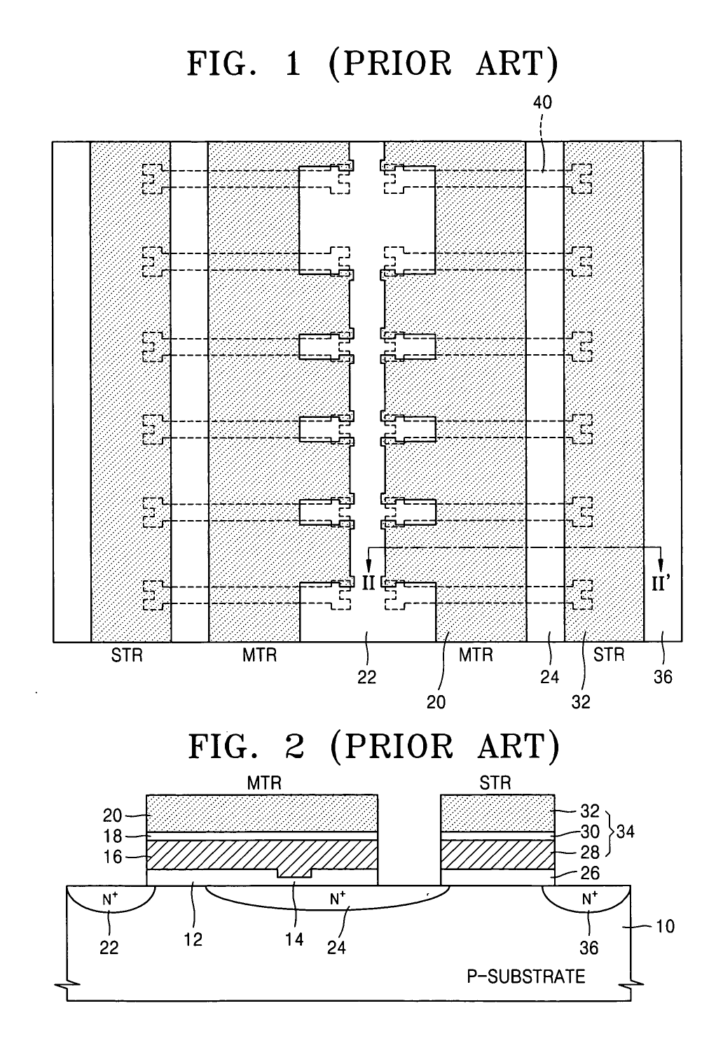

### DETAILED DESCRIPTION OF THE PREFERRED EMBODIMENT

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. It will also be understood that when a layer is referred to as being “on” another layer or substrate, it can be directly on the other layer or substrate, or intervening layers may also be present. Like reference numerals denote like elements throughout the drawings, and thus their repeat description will be omitted.

Hereinafter, an Electrically Erasable and Programmable Read Only Memory (EEPROM) device, being a nonvolatile memory device for electrically programming and erasing information, is described as an example.

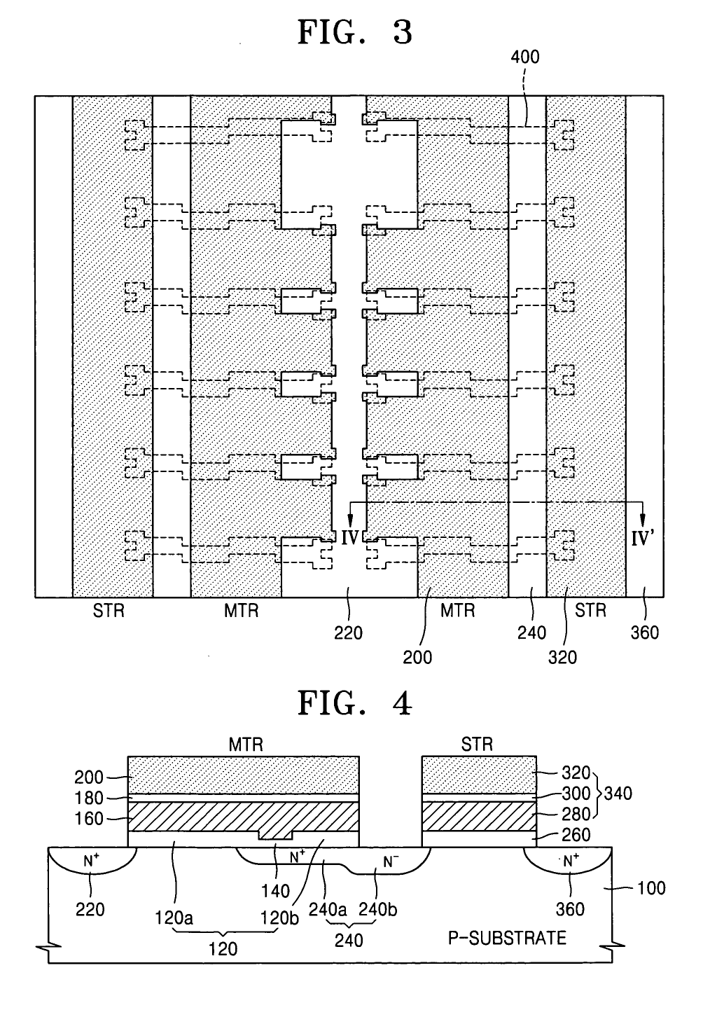

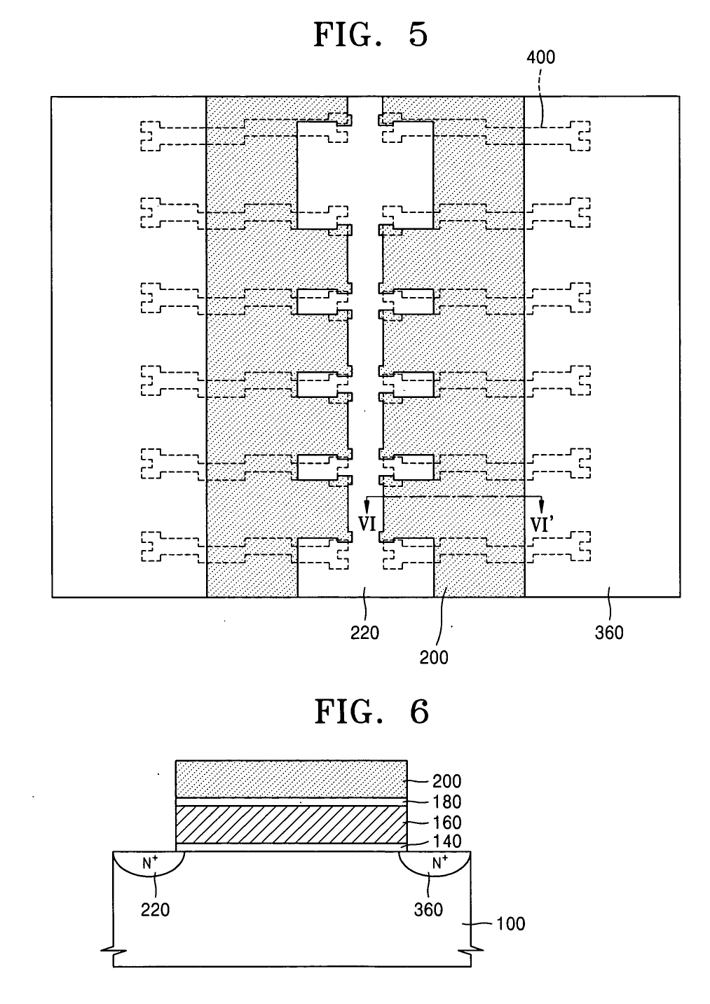

FIG. 3 is a cell layout illustrating an EEPROM device according to the present invention, and FIG. 4 is a sectional view taken along line IV-IV′ of FIG. 3.

FIGS. 3 and 4 show a selection transistor (STR). In this case, a floating junction region 240 can function as a drain region of a memory transistor (MTR). The line IV-IV′ of FIG. 3 represents the direction of a channel length.

In detail, a memory gate oxide film 120 and a tunnel oxide film 140 are formed on a semiconductor substrate 100. The tunnel oxide film 140 is formed in a portion of the semiconductor substrate 100 and is thinner than the memory gate oxide film 120. The memory gate oxide film 120 includes a first memory gate oxide film 120a formed on the semiconductor substrate 100 to a first thickness, and a second memory gate oxide film 120b also of the second thickness and in lateral contact with the tunnel oxide film 140.

A floating gate 160 is formed on the memory gate oxide film 120 and the tunnel oxide film 140. In FIG. 3, a reference numeral 400 denotes a mask pattern for defining a floating gate 160. The defined portion denoted by the reference numeral 400 is an etched portion. Accordingly, in the present invention the floating gate 160 is wave-shaped in the direction of the channel length to improve the coupling ratio, as will later be described in detail. An interlayer insulating film 180 and a control gate 200 are formed on the floating gate 160. In the EEPROM device of the present invention, the memory gate oxide film 120, the tunnel oxide film 140, the floating gate 160, the interlayer insulating film 180 and the control gate 200 are sequentially formed to construct a gate stack.

A source region 220 (first diffusion region) is formed in the semiconductor substrate 100 in alignment with one sidewall of the floating gate 160 and the control gate 200. When the semiconductor substrate 100 is a P-type silicon substrate, the source region 220 is formed using N⁺ impurities by implanting arsenic (As) at 30-80 KeV with a dose of 9.0E14-9.0E15/cm².

A floating junction region 240 (second diffusion region) is formed in alignment with the other sidewall of the floating gate 160 and the control gate 200 in the semiconductor substrate 100 below and to one side of the tunnel oxide film 140. The floating junction region 240 is comprised of an N⁺ impurity region 240a and an N⁻ impurity region 240b. The N⁺ impurity region 240a is formed in the semiconductor substrate 100 below the tunnel oxide film 140 by implanting phosphorus (P) at 50-70 KeV with a dose of 7.0 μl 3-1.0E14/cm², or by implanting arsenic (As) at 60-120 KeV with a dose of 7.0E13-1.5E14/cm², when the semiconductor substrate 100 is a P-type silicon substrate.

The N⁻ impurity region 240b is formed in the semiconductor substrate 100 at the other side of the gate stack by implanting phosphorus (P) at 70-120 KeV with a dose of 5.0 μl 2-1.2E13/cm², when the semiconductor substrate 100 is a P-type silicon substrate. The N⁻ impurity region 240b is deeper than the N⁺ impurity region 240a.

Accordingly, the floating junction region 240 is a dual impurity region comprised of the N⁺ impurity region 240a and the N⁻ impurity region 240b. Therefore, the present invention provides the memory transistor (MTR) comprised of the gate stack, the source region 220 and the floating junction region 240 (that is, the drain region when the selection transistor is not provided).

A selection gate oxide film 260 is spaced apart from the memory transistor (MTR) on the semiconductor substrate 100. A gate 340 is formed on the selection gate oxide film 260. The gate 340 is comprised of a first conductive film pattern 280, an interlay insulating film pattern 300 and a second conductive film pattern 320. A second gate stack is comprised of the selection gate oxide film 260 and the gate 340. A drain region 360 (third diffusion region) is formed in the semiconductor substrate 100 to the right side of the gate 340. A bit line (not shown) is connected to the drain region 360.

When the semiconductor substrate 100 is P-type silicon substrate, the drain region 360 is formed using N⁺ impurities by implanting arsenic (As) at 30-80 KeV with a dose of 9.0E14-9.0E15/cm². As a result, the selection transistor STR (that is, the selection transistor region) is comprised of the selection gate oxide film 260, the gate 340, the floating junction region 240 (that is, the source region of the selection transistor) and the drain region 360.

Hereinafter, a cell of a flash memory device, being a nonvolatile memory device, is described as an example.

FIG. 5 is a cell layout illustrating the flash memory device according to the present invention, and FIG. 6 is a sectional view taken along line VI-VI′ of FIG. 5.

Elements in FIGS. 5 and 6 which are also common to FIGS. 3 and 4 are represented by the same reference numerals.

The line VI-VI′ of FIG. 5 represents the direction of the channel length. In the cell layout of the flash memory device of FIG. 5, the selection transistor is omitted for convenience, in comparison with the cell layout of the EEPROM device of FIG. 3. Of course, the presence of the selection transistor is immaterial to the present invention. Additionally, the flash memory device of FIG. 6 has the same memory transistor as the EEPROM device of FIG. 4 except that the tunnel oxide film is formed differently, and programming and erasing are performed differently.

In more detail, in the inventive cell transistor of the flash memory device, the tunnel oxide film 140 and the floating gate 160 are formed on the semiconductor memory 100. Specifically, the tunnel oxide film 140 is formed on the semiconductor substrate 100 to a regular thickness, unlike in FIG. 4. In FIG. 5, a reference numeral 400 denotes a mask pattern for defining the floating gate 160. The defined portion denoted by the reference numeral 400 is an etched portion. Accordingly, the floating gate 160 is wave-shaped in the direction of the channel length, to improve the coupling ratio, as will later be described in detail. The interlayer insulating film 180 and the control gate 200 are formed on the floating gate 160.

The source region 220 is formed in the semiconductor substrate 100 in alignment with one sidewall of the floating gate 160 and the control gate 200. The drain region 360 is formed in the semiconductor substrate 100 in alignment with the other sidewall of the floating gate 160 and the control gate 200. When the semiconductor substrate 100 is a P-type silicon substrate, the source region 220 and the drain region 360 are formed using N⁺ impurities, by implanting arsenic (As) at 30-80 KeV with a dose of 9.0E14-9.0E15/cm².

As a result, the tunnel oxide film 140, the floating gate 160, the interlayer insulating film 180 and the control gate 200 are sequentially formed to constitute the gate stack. Accordingly, the gate stack, the source region 220 and the drain region 360 constitute the memory transistor (MTR).

In the inventive EEPROM device or flash memory device, a voltage difference between the control gate 200 and the floating junction region 240 causes current to flow through the tunnel oxide film 140. Accordingly, electrons are injected into or emitted from the floating gate 160 to erase or program the cell.

Specifically, in the inventive EEPROM device or flash memory device, both side surfaces of the floating gate 160 are wave-shaped in the direction of the channel length, to increase capacitance between the floating gate 160 and the control gate 200. Accordingly, the inventive EEPROM device or flash memory device can increase the coupling ratio, thereby decreasing the voltage necessary for programming and erasing.

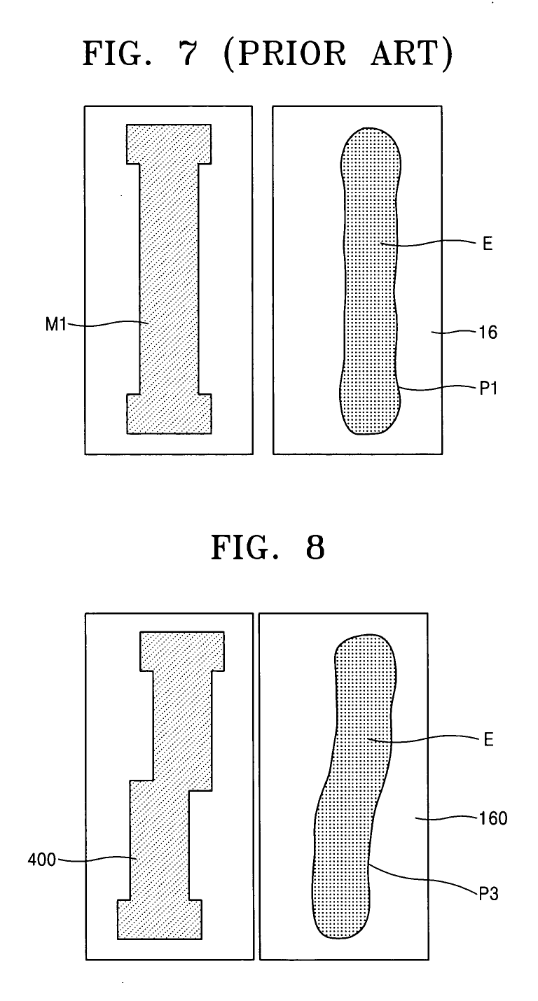

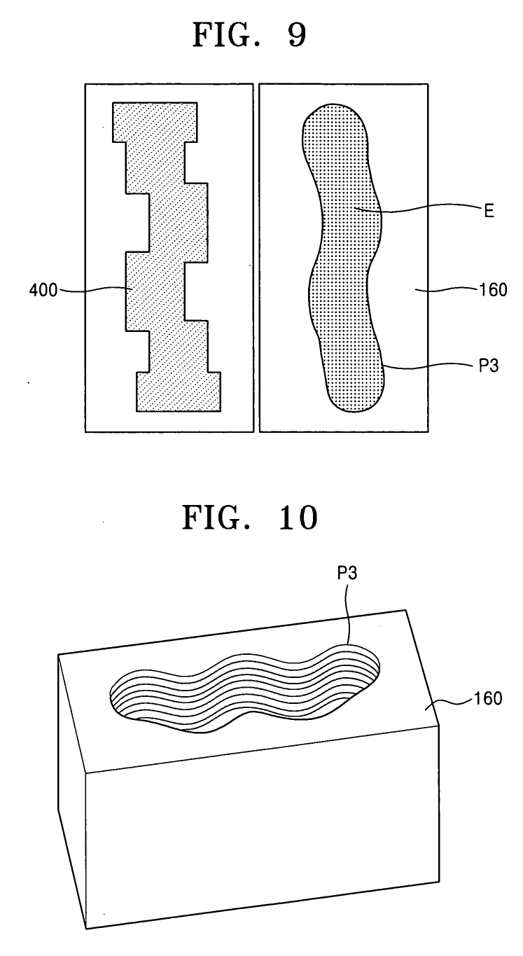

FIG. 7 is a view illustrating a conventional process of patterning a floating gate of a nonvolatile semiconductor memory device, and FIGS. 8 and 9 are views illustrating a process of patterning the floating gate of the nonvolatile semiconductor memory device according to the present invention.

In detail, when a mask pattern M1 of FIG. 7 is used to form the floating gate by photolithography, the floating gate 16 is formed with a regular pattern profile P1 as shown at the right side of FIG. 7. In FIG. 7, the reference “E” denotes the etched portion.

Alternatively, when mask patterns 400 of FIGS. 8 and 9 are used to form the floating gate 160 by photolithography, the floating gate 160 has a wave-shaped pattern profile P3 as shown at the right sides of FIGS. 8 and 9. The wave shape is repeated and has a periodicity of more than two times. In FIGS. 8 and 9, the reference “E” denotes an etched portion. Specifically, the floating gate 160 of FIG. 9 is more strongly wave-shaped than that in FIG. 8. As a result, both side surfaces of the floating gate 160 are wave-shaped in the direction of the channel length.

FIG. 10 is a simulated perspective view of the floating gate of the nonvolatile semiconductor memory device according to the present invention.

In detail, when the mask patterns 400 shown in FIGS. 8 and 9 are used to form the floating gate by photolithography, the floating gate 160 has the wave-shaped pattern profile P3.

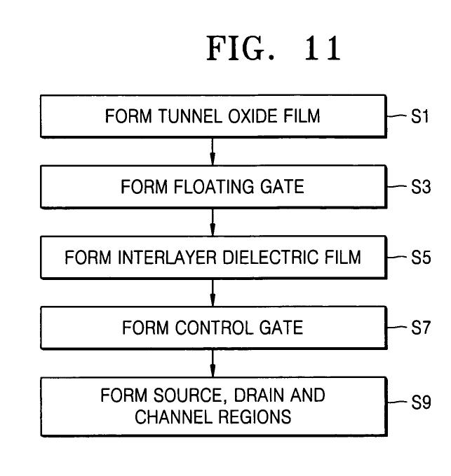

FIG. 11 is a flowchart illustrating a method of fabricating the nonvolatile semiconductor memory device according to the present invention.

In detail, the tunnel oxide film is formed on the semiconductor substrate (S1). When the non-volatile semiconductor memory device is an EEPROM device, the tunnel oxide film is partly formed below where the floating gate will be formed later. When the non-volatile semiconductor memory device is used as flash memory device, the tunnel oxide film is entirely formed to a regular thickness below where the floating gate will be formed later.

Next, the floating gate is formed by photolithography on the tunnel oxide film with both side surfaces wave-shaped in the direction of the channel length, as described in FIGS. 8 through 10 (S3), thereby improving the coupling ratio.

After that, the interlayer insulating film is formed on the floating gate (S5). Next, the control gate is formed on the interlayer insulating film (S7). Thereafter, the source and drain regions are formed in the semiconductor substrate in alignment with both sidewalls of the floating gate and the control gate, and a channel region is formed in the semiconductor substrate 100 between the source and drain regions (S9). Specifically, when the non-volatile semiconductor memory device is an EEPROM device, the drain region is formed in the semiconductor substrate below the tunnel oxide film.

As described above, in the inventive semiconductor memory device, both side surfaces of the floating gate are wave-shaped in the direction channel length, thereby improving the capacitance between the floating gate and the control gate. Accordingly, the inventive non-volatile semiconductor memory device maintains charge retention while increasing the coupling ratio, thereby decreasing the operation voltage necessary for programming and erasing, even if the cell decreases in size.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A nonvolatile semiconductor memory device comprising:
a gate stack which comprises a tunnel oxide film, a floating gate, an interlayer insulating film and a control gate sequentially formed on a semiconductor substrate;
a first diffusion region which is formed in the semiconductor substrate on one side surface of the gate stack;
a second diffusion region which is formed in the semiconductor substrate on the other side surface of the gate stack; and
a channel region which is formed in the semiconductor substrate between the first and second diffusion regions,
wherein both side surfaces of the floating gate are wave-shaped in the direction of the channel length.

2. The device of claim 1, wherein the tunnel oxide film is formed to a predetermined thickness on the semiconductor substrate.

3. The device of claim 2, wherein the first and second diffusion regions are formed in the semiconductor substrate aligned respectively with the side surfaces of the gate stack.

4. The device of claim 1, wherein the tunnel oxide film has a shallow region and a thick region on the semiconductor substrate.

5. The device of claim 1, wherein the gate stack, the first diffusion region and the second diffusion region form a memory transistor region.

6. The device of claim 1, wherein the semiconductor substrate spaced apart from the gate stack forms a selection transistor region.

7. The device of claim 6, wherein the selection transistor region has a second gate stack, and a second diffusion region and a third diffusion region at respective side surfaces of the second gate stack.

8. The device of claim 1, wherein the floating gate is wave-shaped to improve a coupling ratio.

9. The device of claim 1, wherein the wave shape is repeated and has a periodicity of more than two times.

10. A nonvolatile semiconductor memory device comprising:
a memory transistor and a selection transistor which are formed on a semiconductor substrate, wherein
the memory transistor comprises:
a memory gate oxide film which is formed on the semiconductor substrate;
a floating gate which is formed on the memory gate oxide film, having both side surfaces wave-shaped in the direction of a channel length;
an interlayer insulating film and a control gate which are sequentially formed on the floating gate;
a source region which is formed in the semiconductor substrate in alignment with one sidewall of the floating gate and the control gate; and
a floating junction region which is formed in the semiconductor substrate in alignment with the other sidewall of the floating gate and the control gate, and
the selection transistor comprises:
a selection gate oxide film which is spaced apart from the memory transistor;
a selection gate which is formed on the selection gate oxide film;
a source region which uses the floating junction region of the memory transistor; and
a drain region which is formed in alignment with the other sidewall of the selection gate.

11. The device of claim 10, wherein the floating gate is wave-shaped to improve the coupling ratio.

12. The device of claim 10, wherein the wave shape is repeated and has a periodicity of more than two times.

13. The device of claim 10, wherein the memory transistor further comprises a tunnel oxide film formed in the memory gate oxide film and thinner than the memory gate oxide film.

14. The device of claim 10, wherein the floating junction region is formed in the semiconductor substrate below the tunnel oxide film.

15. The device of claim 10, wherein the floating junction region is a dual impurity region comprised of an N⁺ impurity region formed in the semiconductor substrate below the tunnel oxide film, and an N⁻ impurity region formed in the semiconductor substrate below and at the other sidewall of the floating gate and the control gate.

16. The device of claim 15, wherein the N⁻ impurity region is formed deeper into the semiconductor substrate than the N⁺ impurity region.

17. A nonvolatile semiconductor memory device comprising:
a tunnel oxide film which is formed on a semiconductor substrate;
a floating gate which is formed on the tunnel oxide film, having both side surfaces wave-shaped in the direction of a channel length;
an interlayer insulating film and a control gate which are sequentially formed on the floating gate;
a source region which is formed in the semiconductor substrate in alignment with one sidewall of the floating gate and the control gate; and
a drain region which is formed in the semiconductor substrate in alignment with the other sidewall of the floating gate and the control gate.

18. The device of claim 17, wherein the tunnel oxide film is formed to a predetermined thickness on the semiconductor substrate.

19. The device of claim 17, wherein the floating gate is wave-shaped to improve the coupling ratio.
